(19) United States
(12) Patent Application Publication
(10) Pub. No.: US 2014/0340854 A1
(43) Pub. Date: Nov. 20, 2014

(54) ELECTRONIC DEVICE AND METHOD OF MANUFACTURING THE ELECTRONIC DEVICE

(71) Applicants: Yoshikazu Akiyama, Kanagawa (JP); Akira Shimofuku, Kanagawa (JP); Atsushi Takeuchi, Kanagawa (JP); Osamu Machida, Kanagawa (JP)

(72) Inventors: Yoshikazu Akiyama, Kanagawa (JP); Akira Shimofuku, Kanagawa (JP); Atsushi Takeuchi, Kanagawa (JP); Osamu Machida, Kanagawa (JP)

(21) Appl. No.: 14/278,085

(22) Filed: May 15, 2014

(30) Foreign Application Priority Data
May 15, 2013 (JP) 2013-103357

(51) Int. Cl. H05K 1/18; H05K 3/46

(52) U.S. Cl. CPC H05K 1/18; H05K 3/467
USPC 361/748; 427/100; 427/126.3

(57) ABSTRACT

An electronic device includes a substrate; and a plurality of thin-film elements formed on the substrate. Further, the thin-film element includes a thin-film section having a function selected from a group including piezoelectric effect, inverse piezoelectric effect, charge storage, semiconductivity, and conductivity, and the plurality of thin-film elements includes the thin-film sections having two or more different functions.

### CROSS-REFERENCE TO RELATED APPLICATIONS

The present application is based on and claims the benefit of priority under 35 U.S.C §119 of Japanese Patent Application No. 2013-103357 filed May 15, 2013, the entire contents of which are hereby incorporated herein by reference.

### BACKGROUND OF THE INVENTION

1. Field of the Invention

The present invention generally relates to an electronic device and a method of manufacturing the electronic device.

2. Description of the Related Art

In the related technologies, there has been known an electronic device in which one thin-film element is formed on a substrate.

For example, Japanese Laid-open Patent Publication No. 2000-22233 discloses an example structure of an electronic device in which a piezoelectric thin film element includes a piezoelectric-body film sandwiched between the lower electrode and the upper electrode.

### SUMMARY OF THE INVENTION

According to an aspect of the present invention, an electronic device includes a substrate; and a plurality of thin-film elements formed on the substrate. Further, the thin-film element includes a thin-film section having a function selected from a group including piezoelectric effect, inverse piezoelectric effect, charge storage, semiconductivity, and conductivity, and the plurality of thin-film elements includes the thin-film sections having two or more different functions.

### BRIEF DESCRIPTION OF THE DRAWINGS

Other objects, features, and advantages of the present invention will become more apparent from the following description when read in conjunction with the accompanying drawings, in which:

FIG. 1 schematically illustrates a method of manufacturing an electronic device including a plurality of thin-film elements based on a conventional technique;

FIG. 2 illustrates an example structure of an electronic device according to an embodiment of the present invention;

FIG. 3 illustrates a process of reforming a substrate surface in a method of manufacturing the electronic device according to an embodiment;

FIG. 4 illustrates a process of forming a plurality of thin film elements in the method of manufacturing the electronic device according to an embodiment;

FIG. 5 illustrates the process of forming the thin film elements in the method of manufacturing the electronic device according to the embodiment;

FIG. 6 illustrates a crystallization process in the method of manufacturing the electronic device according to the embodiment;

FIG. 7 illustrates a process of reforming the substrate surface in a method of manufacturing the electronic device according to an embodiment;

FIG. 8 illustrates the process of reforming the substrate surface in the method of manufacturing the electronic device according to the embodiment;

FIG. 9 illustrates the process of reforming the substrate surface in the method of manufacturing the electronic device according to the embodiment; and

FIG. 10 illustrates an example structure of an electronic device according to an embodiment.

### DETAILED DESCRIPTION OF THE PREFERRED EMBODIMENTS

In related technologies, as disclosed in Japanese Laid-open Patent Publication No. 2000-22233, it is possible to acquire the electronic device including a thin-film element having a single function. However, due to recent requirements for reducing the size and the cost of an apparatus, it is desired that the electronic device includes a plurality of thin-film elements having two or more different functions. However, such an electronic device including a plurality of thin-film elements having two or more different functions has been difficult to be achieved so far.

As a method of manufacturing an electronic device including a plurality of thin-film elements having two or more different functions on a substrate, the following method is supposed.

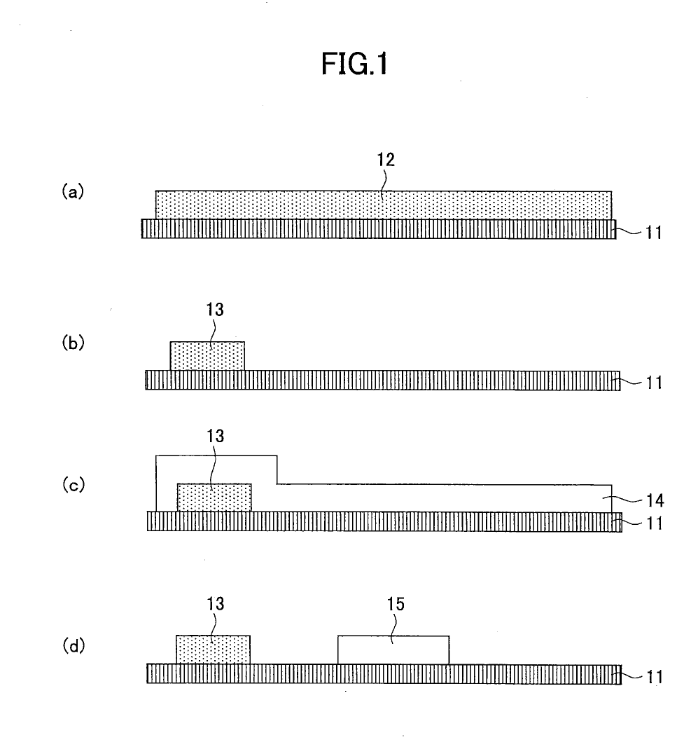

First, as shown in part (a) of FIG. 1, a thin film 12 is formed on the entire surface of the substrate 11 by, for example, a spin-coating method. Next, as shown in part (b) of FIG. 1, one thin-film element 13 is formed by etching. Then, as shown in part (c) of FIG. 1, a thin film 14, which is made of a material for another thin-film element, is formed on the substrate 11. Then, as shown in part (d) of FIG. 1, another thin-film element 15 is formed by etching. Depending on cases, the above process may be repeated plural times so as to form a plurality of thin-film elements.

According to the above method, when the thin film 14 is formed, the thin-film element 13 is already formed on the substrate 11. Therefore, the thin film 14 is formed in a concavo-convex shape on the substrate 11. However, due to the concavo-convex shape of the thin film 14 formed on the substrate 11, it is difficult to form a uniform thin film 14. As a result, it is difficult to form the thin-film element 15 having a desired performance.

Further, when the material composition of the thin-film element 13 differs from the material composition of the thin-film element 15, the heat treatment temperatures are also different therebetween. Therefore, when one thin-film element is in a heat process thereof, the function of the other thin-film element may be impaired. Also, the selection ratio during the etching is not sufficiently great.

Therefore, it may be difficult to form the thin-film elements so as to have the respective desired shapes. Due to the above reasons as well, it is difficult to form a plurality of thin-film elements 15, which have different functions, on the substrate 11. Further, for example, when the thin films 12 and 14 include oxide, due to the selection ratio which is not sufficiently great in the etching, it is difficult to form the thin-film elements 13 and 15.

The present invention is made in light of the above problems in related technologies, and may provide an electronic device that includes a plurality of thin-film element having two or more different functions.

In the following, embodiments of the present invention are described with reference to the accompanying drawings. However, it should be noted that the present invention is not limited to the examples.

An example structure of an electronic device according to an embodiment is described.

An electronic device according to an embodiment includes a substrate and a plurality of thin-film elements formed on the substrate. Further, the thin-film element includes a thin-film section having a function selected from a group including piezoelectric effect, inverse piezoelectric effect, charge storage, semiconductivity, and electrical conductivity (herein may be simplified “conductivity”). Further, the plurality of the thin-film elements includes two or more different functions.

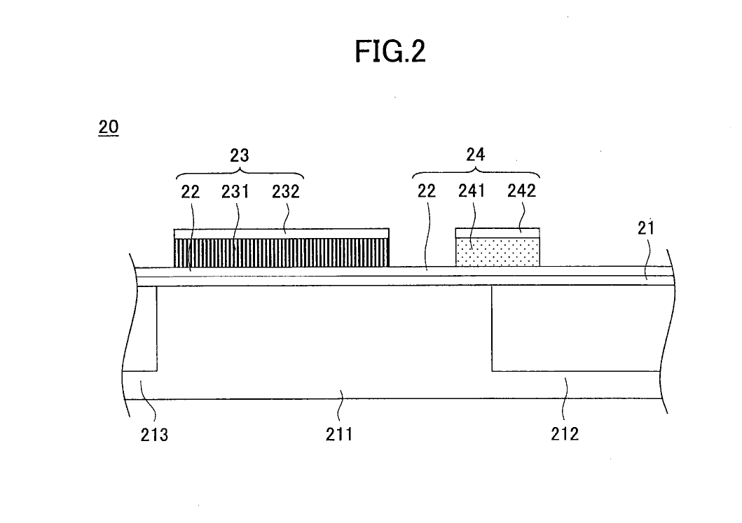

An example of a specific structure is described with reference to FIG. 2. FIG. 2 is a cross-sectional drawing of an electronic device 20 where two thin-film elements are formed on a substrate 21. In FIG. 2, a first thin-film element 23 and a second thin-film element 24 are formed above the substrate 21. Here, it should be noted that the number of thin-film elements is not limited to two. Namely, three or more thin-film elements may be formed on the substrate 21.

Here, the structure of the first thin-film element 23 and the second thin-film element 24 is not limited. However, for example, as shown in FIG. 2, the first thin-film element 23 and the second thin-film element 24 may include respective thin-film sections 231 and 241. The thin-film sections 231 and 241 provide respective functions of the thin-film elements and are sandwiched between respective upper and lower electrodes formed on the upper and lower surfaces of the thin-film sections 231 and 241.

More specifically, as the individual electrodes of the first thin-film element 23 and the second thin-film element 24, the first thin-film element 23 has an upper electrode 232 and a lower electrode 22, and the second thin-film element 24 has an upper electrode 242 and the lower electrode 22. However, when a plurality of thin-film elements are formed, the thin-film elements may have respective individual upper and lower electrodes of the thin-film elements.

Further, the material of the upper and lower electrode is not limited. Namely, any of various electrically conductive materials may be used. However, as the material of the upper and lower electrode, it is preferable to use a metal such as platinum, rhodium, iridium, ruthenium, palladium, silver, nickel or the like, an alloy thereof, or conductive oxide material such as ITO described below.

Further, as described above, the thin-film elements include the respective thin-film sections having a function selected from a group including piezoelectric effect, inverse piezoelectric effect, charge storage, semiconductivity, and conductivity. Especially, it is preferable that the first thin-film element 23 and the second thin-film element 24 include the thin-film sections 231 and 241, respectively, having a function selected from a group including piezoelectric effect, inverse piezoelectric effect, and charge storage. As a result, the thin-film element has the function same as that of the thin-film section of the thin-film element.

Here, the thin-film section having the piezoelectric effect refers to a thin-film section having a function of converting pressure into electricity. As an example of the thin-film element having the function of the piezoelectric effect, there is a sensor that outputs electricity indicating the pressure change due to positional movement or the like.

Further, the thin-film section having the inverse piezoelectric effect refers to a thin-film section having a function of converting applied voltage into displacement so as to be deformed. As an example of the thin-film element having the function of the inverse piezoelectric effect, there is an actuator.

The thin-film section having the charge storage refers to a thin-film section having a function of accumulating electrical charges when a voltage is applied. As an example of the thin-film element having the function of the charge storage, there is a capacitor.

As an example of the thin-film element having the function of the semiconductivity, there is a semiconductor layer in a device such as a Field Effect Transistor (FET) and a diode.

The thin-film section having the conductivity refers to a thin-film section having a function of a path for flowing a current when a voltage is applied. As an example of the thin-film element having the function of the conductivity, there is a wired line.

Here, as a material of the thin-film section, a desired material providing the above performances may be selected and used. Especially, due to easiness of processing, it is preferable that the thin-film section is made of a metal-oxide film.

A metal oxide including such a metal-oxide film is not limited to a specific metal oxide. Namely, an appropriate metal oxide depending on the required function of the thin-film section may be selected and used. For example, a conductive oxide, an oxide semiconductor, an oxide insulator, a piezoelectric body or the like may be used. For example, such a conductive oxide includes ITO (In₂O₃—SnO₃), ZnO, Al added ZnO, SnO₂, In₂O₃, (La,Sr)CoO₃, LaMnO₃, LaNiO₃, SrRuO₃, etc. For example, such an oxide semiconductor includes IGZO (registered trademark), InMgO₄, ZnO, Nb added SrTiO₃, etc. For example, such an oxide insulator includes HfO₂, ZrO₂, Ta₂O₅, SiTiO₃, (Ba,Sr)TiO₃, etc. For example, such a piezoelectric body includes PTZ (PbTiO₃—PbZrO₃), PbTiO₃, BaTiO₃, Bismuth Layer Structure Ferroelectric (BLSF), KNbO₃—NaNbO₃, BiFeO₃, (Bi,Na)TiO₃, Bi(Zn,Ti)O₃, etc.

For example, when the thin-film section includes the piezoelectric effect or the inverse piezoelectric effect, it is preferable that the thin-film section is made of the piezoelectric body from among the materials described above. Further, for example, when the thin-film section includes the function of charge storage, it is preferable that the thin-film section is made of the oxide insulator from among the materials described above.

Further, for example, when the thin-film section includes the function of semiconductivity, it is preferable that the thin-film section is made of the oxide semiconductor from among the materials described above. Further, for example, when the thin-film section includes the function of conductivity, it is preferable that the thin-film section is made of the conductive oxide from among the materials described above. Further, it is not necessary that the thin-film section is made of one type of material and may include a plurality of materials.

The thin-film section of the thin-film element is not limited to a single layer and may include a plurality of layers. Specifically, for example, in a case where the thin-film section has a function of semiconductivity and the thin-film element has a diode function, a p-type semiconductor layer made of ZnO and an n-type semiconductor layer made of IGZO may be laminated.

Further, the electronic device 20 include a plurality of thin-film elements. However, it is not necessary that the thicknesses of the thin-film elements are equal to each other, and may vary depending on, for example, the functions required of the thin-film elements. When the ink jet method is used to laminate layers of the thin-film element, by selecting (adjusting) the density, amounts, of discharged liquid droplets, the number of applications (discharges), it becomes possible for the layers of the thin-film element to have desired thicknesses.

Further, when the thin-film section is formed, in order to control the crystalline orientation of the thin-film section, a seed layer may be formed in a lower layer part of the thin-film section.

As shown in FIG. 2, the electronic device 20 according to this embodiment includes a plurality of thin-film elements and the plurality of thin-film elements include two or more functions of the thin-film sections. Namely, each thin-film element has one thin-film section having one function, and a plurality of the thin-film elements include thin-film elements having respective thin-film sections having different functions from each other.

Here, the function refers to a function which is selected from a group including the piezoelectric effect, the inverse piezoelectric effect, the charge storage, the semiconductivity, and the conductivity. Further, it is preferable that the function is selected from a group including the piezoelectric effect, the inverse piezoelectric effect, and the charge storage.

In the electronic device according to this embodiment, the plurality of the thin-film elements include thin-film sections having different functions. Therefore, it becomes possible to have a structure including a plurality of thin-film elements so as to have two or more different functions.

For example, the electronic device 20 of FIG. FIG. 2 includes two thin-film elements. Therefore, the thin-film sections 231 of the first thin-film element 23 has a function different from the function of the thin-film section 241 of the second thin-film element 24. Further, when three or more thin-film elements are included, those thin-film elements may have functions different from each other, or some of the thin-film elements may have the same function.

As an example structure of the electronic device 20 of FIG. 2, the first thin-film element 23 is an actuator and the second thin-film element 24 is a sensor. In this case, the thin-film section 231 of the first thin-film element 23 has the function of the inverse piezoelectric effect and the thin-film section 241 of the second thin-film element 24 has the function of the piezoelectric effect.

For example, in an actuator, the displacement amount relative to a predetermined voltage of the actuator may vary over time. To overcome the inconvenience, in the electronic device 20 of FIG. 2, it is possible to detect the displacement amount of the actuator, which is the first thin-film element 23, by using the sensor, which is the second thin-film element 24, so as to control the voltage amount to be applied to the first thin-film element 23 based on the detected value (amount).

For example, in the electronic device 20 of FIG. 2, a liquid chamber 211, which is in communication with a liquid supply path 212 and a liquid discharge path 213, is formed on the lower surface of the substrate 21. Further, by the displacement of the actuator, the first thin-film element 23 has a function of a liquid feed pump. In this case, the displacement amount of the first thin-film element 23 is detected by the sensor (i.e., the second thin-film element 24) so as to control the voltage to be applied to the first thin-film element 23 to obtain a desired displacement amount, thereby enabling stable liquid feeding.

As the structure (configuration) of the electronic device, the present invention is not limited to the above structure. As an another example, the plurality of the thin-film elements may include a sensor and a power generation element. Further, as another example, the plurality of the thin-film elements may include a power generation element and an electric charge device.

As described above, when the electronic device 20 includes a plurality of thin-film elements collectively having two or more different functions, it is preferable that the thin-film sections of the thin-film elements be made of optimal material depending on the required functions of the thin-film sections. Therefore, it is preferable for the plurality of the thin-film elements to include the thin-film sections having different material compositions.

The thin-film sections of the thin-film elements in the electronic device 20 are made of respective material in accordance with the functions thereof. The manufacturing method of the thin-film sections according to this embodiment is not limited to a specific method. However, it is preferable to use an ink jet method. Further, when the thin-film elements include the respective thin-film sections and the upper and/or lower electrode(s) which are (is) an electrode section(s), it is also preferable that the electrode section is formed by the ink jet method. As describe above, it is preferable that the thin-film elements are formed by the ink jet method.

In the ink jet method, sol-gel liquid, which is a material of the electrode section and the thin-film section, is applied (discharged) to a predetermined a position and a range on a substrate by using a liquid discharge head. Then, the discharged sol-gel liquid is evaporated, thermally decomposed, crystallized, and these processes are repeated when necessary to form the electrode section and the thin-film section.

When the ink jet method is used, it becomes possible to form a film only at a desired position on the substrate. Therefore, it is not necessary to perform an etching process. Due to this feature, it becomes possible to reduce the amount of material to be disposed of, so as to improve the productivity.

Further, before the sol-gel liquid is applied by the ink jet method, it is preferable that the substrate surface is reformed, so that the sol-gel liquid can be applied only to a part where the thin-film element is to be formed. To that end, for example, a self-assembled monolayer (SAM) film, which is a hydrophobic film, is formed on the part where the thin-film element is not to be formed on the substrate, so that the sol-gel liquid can be applied to only a part where the thin-film element is to be formed. In this case where the SAM film is formed, it is preferable that the substrate be a platinum plate or a substrate having a surface on which a platinum film is formed.

Further, it is preferable that the plurality of the thin-film elements in the electronic device collectively include the thin-film sections which are made of different material compositions as described above. In this case, in order to simultaneously form the thin-film sections made of different material compositions, it is preferable that a liquid discharge head having a multiple nozzles be used.

It is preferable that the liquid discharge head having a multiple nozzles include multiple liquid discharge heads that discharge respective sol-gel liquids formed of material compositions different from each other. By doing this, it becomes possible to simultaneously form the thin-film sections which are formed of different material compositions on the substrate, thereby improving the productivity.

In the above description, an electronic device according to an embodiment is described. In the embodiment, it is possible to provide an electronic device including a plurality of thin-film elements having two or more different functions. Therefore, it becomes possible to reduce the size and the cost of the electronic device.

Next, a method of manufacturing an electronic device according to an embodiment is described.

The method of manufacturing an electronic device according to an embodiment includes a step of forming a plurality of thin-film elements on the substrate by using a liquid discharge head having multi-nozzles. Further, the thin-film element includes the thin-film section having a function selected from a group including piezoelectric effect, inverse piezoelectric effect, charge storage, semiconductivity, and conductivity, so that the plurality of thin-film elements includes the thin-film sections that collectively include two or more different functions.

The structure (configuration) of the electronic device according to this embodiment is the same as that of the electronic device described above. Therefore, the repeated description thereof is herein omitted.

As described, by forming the thin-film element using the liquid discharge head, it becomes possible to form the thin-film element at a desired position and area on the substrate without performing an etching process, etc. Therefore, it becomes possible to easily form a plurality of thin-film elements and improve the productivity.

Further, by using a liquid discharge head having multi-nozzles, it becomes possible to simultaneously form the thin-film elements having different compositions. Therefore, it is preferable to use the liquid discharge head having multi-nozzles due to improved productivity.

Especially, it is preferable that the liquid discharge head having multi-nozzles includes multiple liquid discharge heads so as to discharge sol-gel liquids having different material compositions. By having this feature (structure), it becomes possible to simultaneously form the thin-film sections having different material compositions on the substrate. Therefore, an alignment operation to fit the landing target position of the liquid droplets to the landing position on the substrate can be performed only once. Therefore, it become possible to improve the productivity, which is desirable.

Further, in the method of manufacturing the electronic device according to this embodiment, before the step of forming the plurality of thin-film elements, it is possible to add a step of reforming the substrate surface.

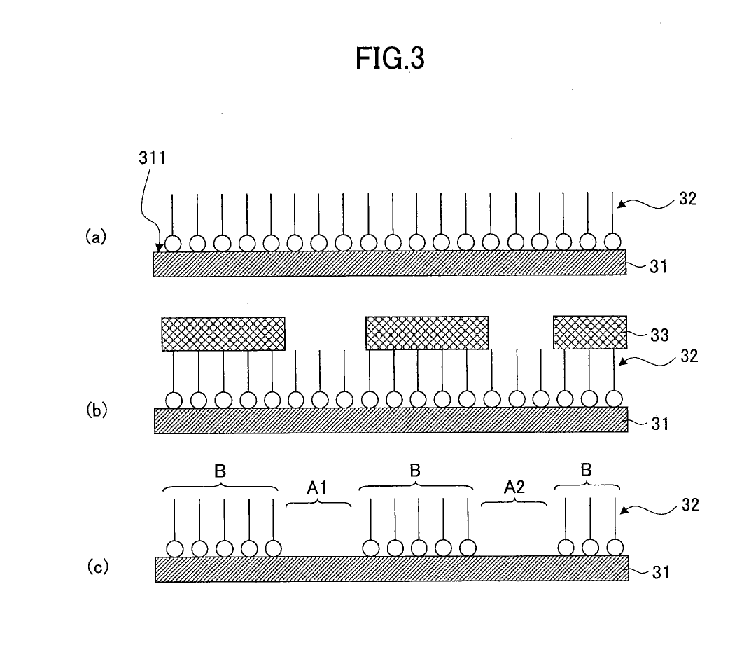

A method of manufacturing the plurality of thin-film elements in the case including the step of reforming the substrate surface is described with reference to FIGS. 3 through 5.

The step of reforming the substrate surface is described with reference to FIG. 3. First, a substrate 31 is prepared. In this case, it is preferable that at least an outermost surface 311 of the substrate 31 is made of platinum. In this regard, it is preferable that the substrate 31 is a platinum plate or a substrate, such as a Si substrate, having a surface on which a platinum film is formed. In the case of use of the substrate, such as the Si substrate, having a surface on which a platinum film is formed, the platinum film may be used as the lower electrode.

Then, as shown in part (a) of FIG. 3, a SAM (Self-Assembled Monolayer) film 32 is formed on the substrate 31.

The SAM film 32 may be formed by, for example, applying a SAM material including alkanethiol on the substrate 31. The alkanethiol to be used herein is not limited to a specific one, but it is preferable that the carbon chain from C6 to C18 is included in the alkanethiol. Then, the alkanethiol is dissolved in a general organic solvent such as alcohol, acetone, toluene, etc., to form a solution, which is to be used as the SAM material.

A method of applying the SAM material on the substrate 31 is not limited. However, for example, the SAM film 32 may be formed on the surface of the substrate 31 by dipping the substrate 31 into the solution of the SAM material, taking out the substrate 31 from the solution after a certain time period, performing displacement washing on the substrate 31 to remove extra molecules, and drying the substrate 31.

Next, as shown in part (b) of FIG. 3, a pattern of photoresist 33, which has openings where the thin-film elements are to be formed, is formed by photolithography. Then, as shown in part (c) of FIG. 3, the SAM film 32 is remove by dry etching, and the photoresist 33, used for the pattern forming, is further removed to terminate the patterning of the SAM film 32. By doing this, the parts B where the SAM film 32 remains become hydrophobic, and parts A1 and A2 where the SAM film 32 is removed becomes hydrophilic.

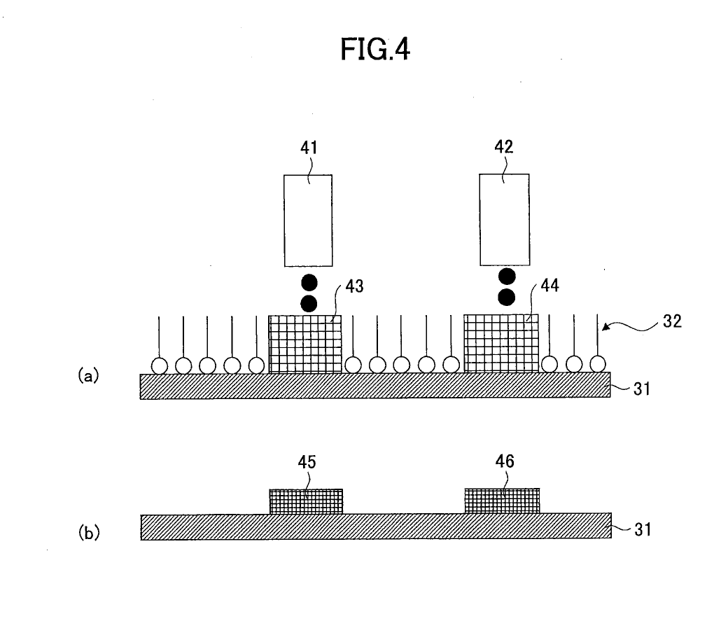

After the step of reforming the substrate surface as shown in parts (a) through (c) of FIG. 3, the step of forming the plurality of the thin-film elements is performed. For example, as shown in part (a) of FIG. 4, the sol-gel liquids, which becomes the materials of the thin-film elements, are applied to the hydrophilic parts A1 and A2 by using a liquid discharge head equipped with multi-nozzles 41 and 42 to form first and second precursors 43 and 44, respectively.

After that, as shown in part (b) of FIG. 4, by drying solvent, thermally decomposing, and crystallizing, a first layer 45 of a first thin-film element and a first layer 46 of a second thin-film element are formed. Here, if a desired film thickness is acquired by applying the sol-gel liquids once, evaporating solvent, thermally decomposing, and crystallizing the first layer 45 of the first thin-film element and the first layer 46 of the second thin-film element become the first thin-film element and the second thin-film element, respectively.

Further, the step of forming the plurality of thin-film elements may be repeated. In this case, first, the first layer 45 of the first thin-film element and the first layer 46 of the second thin-film element are formed, and washed with isopropyl alcohol. Next, similar to the step in part (a) of FIG. 3, the SAM film 51 is formed.

In this case, the SAM film 51 is not formed on the surfaces of the first layer 45 of the first thin-film element and the first layer 46 of the second thin-film element. Therefore, the photolithography of part (b) of FIG. 3 is not necessary. Next, similar to the step in part (a) of FIG. 4, sol-gel liquids, which become the materials of the thin-film elements, are applied on the first layer 45 of the first thin-film element and the first layer 46, which are formed in the step in part (b) of FIG. 4, by using the liquid discharge head equipped with the multi-nozzles 41 and 42.

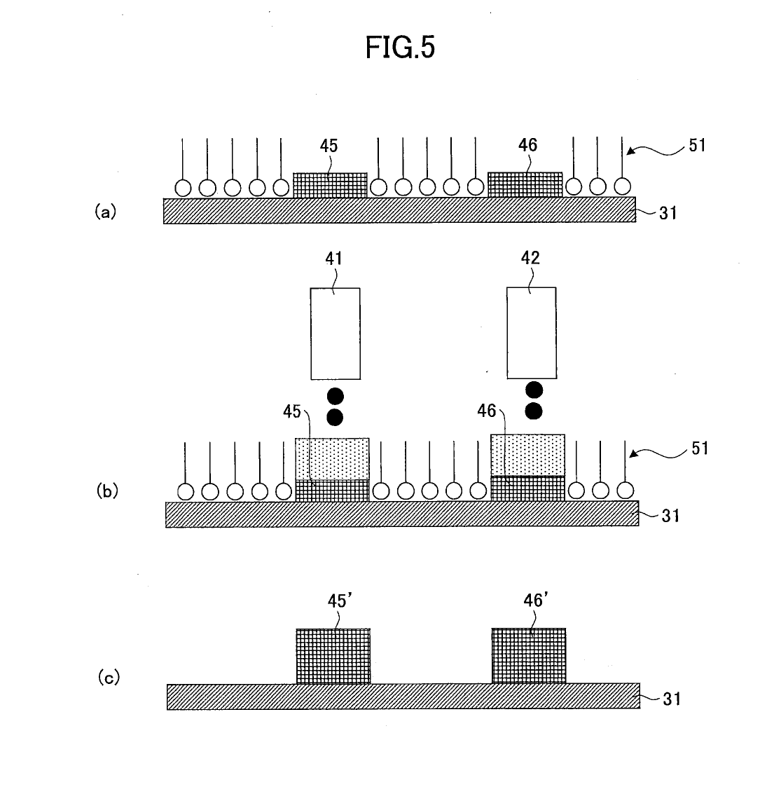

Then, similar to the case of forming the first layers 45 and 46, by evaporating solvent, thermally decomposing, and crystallizing a first thin-film element 45′ and a second thin-film element 46′ in part (c) of FIG. 5 are formed. Further, when desired, the steps in FIG. 5 may be repeated so as to acquire a desired film thickness.

In the above description, a case is described where after the sol-gel liquids, which become the materials of the first thin-film element and the second thin-film element, are applied, the solvent evaporation, the thermal decomposition, and crystallization are performed for each layer. However, the present invention is not limited to this case. For example, after the sol-gel liquids are applied, the solvent evaporation and the thermal decomposition may be performed for each layer, but the crystallization may be collectively performed after multiple layers are formed.

Further, in a case where at least one of the first thin-film element and the second thin-film element includes plural different layers, the type of liquid to be applied by the liquid charge head may be changed in the middle of the method.

Further, the heating temperatures in the crystallization is not specifically limited, and may be selected based compositions of the first thin-film element and the second thin-film element.

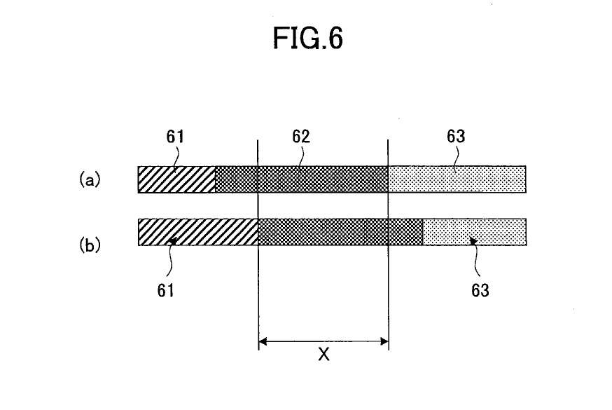

Generally, the heating temperature (range) which are necessary to acquire desired functions are determined based on the materials. An example is described with reference to part (a) of FIG. 6 where the heating temperature is lower in the left-hand side and is higher in the right-hand side. In this case, when the heating temperature in the temperature range 61 is used, the heating temperature is too low, so that the desired function cannot be acquired.

On the other hand, when the heating temperature in the temperature range 63 is used, the heating temperature is too high, so that the material is thermally decomposed and the desired function cannot be acquired. However, the heating temperature in the temperature range 62, which is between the temperature range 61 and the temperature range 63, is an optimal temperature range to acquire the desired function.

In the case of part (b) of FIG. 6 where there is a material different from that in part (a) of FIG. 6, there is also a temperature range 62 which is an optimal temperature range to acquire the desired function. Therefore, when the material compositions of the thin-film elements to be formed on the substrate differ from each other, for example, when the thin-film elements, which are made of materials in parts (a) and (b) of FIG. 6, are simultaneously formed, it is preferable to use the heating temperature in the temperature range X which is overlapped by the temperature range 62 in part (a) of FIG. 6 and the temperature range 62 in part (b) of FIG. 6.

In the above description, a case of the electronic device including two thin-film elements is described. However, the present invention does not limit the number of thin-film elements to a specific number such as two. Namely, for example, three or more thin-film elements may also be formed in the electronic device according to the present invention. In such a case where the number of the thin-film elements is three or more, it is also possible to form the electronic device based on a method similar to the method described above.

Further, the step of reforming the substrate surface may be performed based on the method described below.

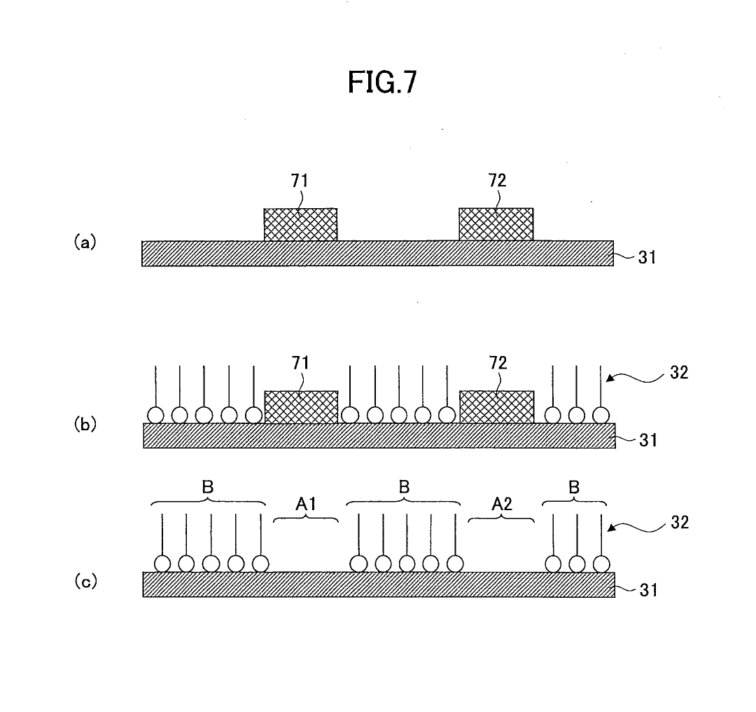

A second method of reforming the substrate surface is described with reference to FIG. 7. The same reference numerals are used to describe the same elements described in FIG. 3.

First, as shown in part (a) of FIG. 7, photoresists 71 and 72 are used to form a resist pattern. Next, the SAM film 32 is formed as shown in part (b) of FIG. 7. In this case, the SAM film 32 is not formed on the hydrophobic photoresists 71 and 72 and the SAM film 32 can be formed on the areas other than the areas of the hydrophobic photoresists 71 and 72.

Then, by removing the photoresists 71 and 72 as shown in part (c) of FIG. 7, the patterning of the SAM film 32 is completed, and the step of reforming the substrate surface is completed. After that, by performing the steps of forming the plurality of the thin-film elements described above, the first thin-film element and the second thin-film element can be formed.

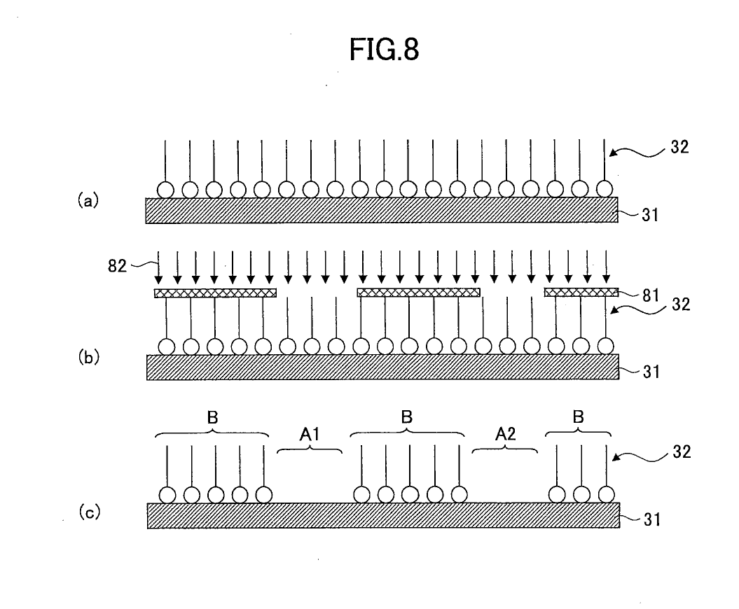

Next, a third method of reforming the substrate surface is described with reference to FIG. 8. The same reference numerals are used to describe the same elements described in FIG. 3.

First, as shown in part (a) of FIG. 8, the SAM film 32 is formed on the surface of the substrate 31. Then, as shown in part (b) of FIG. 8, ultraviolet light is irradiated onto the SAM film 32 on which a patterned mask 81 is formed.

As a result, as shown in part (c) of FIG. 8, the SAM film 32 remains in the areas where the SAM film 32 is not exposed to the ultraviolet light and the SAM film 32 is removed in the areas where the SAM film 32 is exposed to the ultraviolet light, so that the patterning of the SAM film 32 is completed and the step of reforming the substrate surface is completed. After that, by performing the steps of forming the plurality of the thin-film elements described above, the first thin-film element and the second thin-film element can be formed.

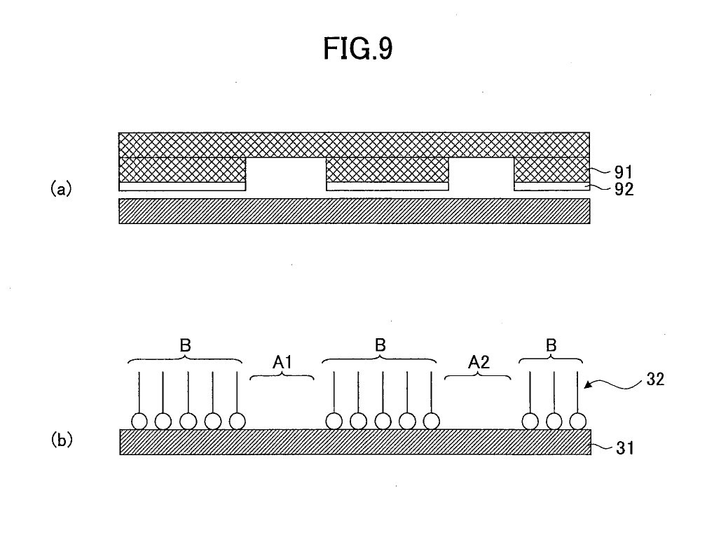

Next, a fourth method of reforming the substrate surface is described with reference to FIG. 9. The same reference numerals are used to describe the same elements described in FIG. 3.

First, as shown in part (a) of FIG. 9, by using so-called a micro-contact print method, a liquid 92, which is to form the SAM film 32, is applied by dipping or spin coat onto a PDSMS stamp 91 which is patterned in advance by soft lithography. Then, by contact printing the PDSMS stamp 91 onto the substrate 31, the patterned SAM film 32 is formed on the substrate 31 as shown in part (b) of FIG. 9.

By doing this, the patterning of the SAM film 32 is completed and the step of reforming the substrate surface is completed. After that, by performing the steps of forming the plurality of the thin-film elements described above, the first thin-film element and the second thin-film element can be formed.

By using the method of manufacturing the electronic device according to an embodiment described above, it becomes possible to manufacture (form) an electronic device including a plurality of thin-film elements having two or more different functions on the substrate. Further, the thin-film elements are formed by using the ink jet method. Therefore, it becomes possible to reduce the amount of material to be wasted and the cost, and improve the productivity.

### Example

In the following, the present invention is further described with reference to a specific example (embodiment). However, it should be noted that the present invention is not limited to the example.

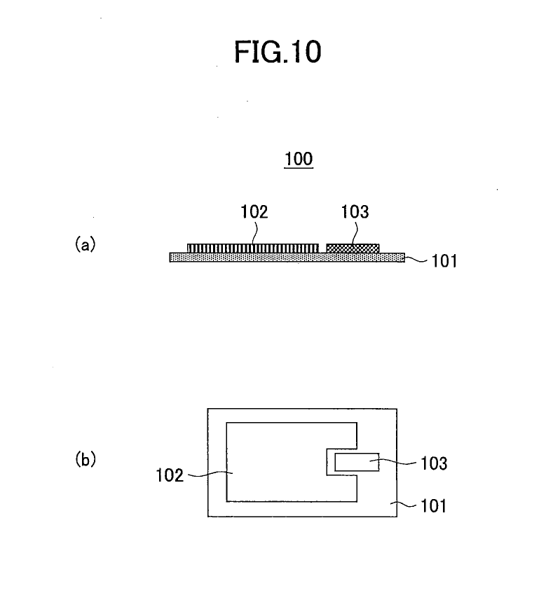

In this example, as shown in FIG. 10, an electronic device in which two thin-film elements are formed on a substrate 101 is formed. Part (a) of FIG. 10 is a cross-sectional view of an electronic device 100 manufactured in this example. Part (b) of FIG. 10 is a top view of the electronic device 100.

As shown in FIG. 10, the electronic device 100 includes two thin-film elements, which are an actuator as a first thin-film element 102 and a sensor as a second thin-film element 103.

A method of manufacturing the electronic device 100 is described.

First, as the substrate 101, a substrate was prepared where a platinum film had been formed on a Si substrate by sputtering. The platinum film was used as the lower electrodes of the first thin-film element 102 and the second thin-film element 103.

Further, the SAM film was used on the surface of the substrate 101 by the method of FIG. 3. As the SAM film, alkanethiol (CH₃(CH₂)ₙ—SH) solution is used. Namely, the substrate 101 was dipped into the alkanethiol (CH₃(CH₂)ₙ—SH) solution, and displacement washing was performed on the substrate 101 to remove extra molecules. Then, the substrate 101 was dried to form the SAM film on the surface of the substrate 101.

Next, a photoresist pattern, which included openings corresponding the parts where the thin-film elements were to be formed, was formed by photolithography. Further, the SAM film in the parts (areas) where the first thin-film element 102 and the second thin-film element 103 were to be formed was removed by dry etching. Further, the photoresist was removed.

Next, by the steps in FIG. 4, the thin-film sections of the first thin-film element 102 and the second thin-film element 103 were formed. Specifically, sol-gel liquids were applied to the parts where the first thin-film element 102 and the second thin-film element 103 were to be formed by using the liquid discharge head equipped with the multi-nozzles, and then the solvent evaporation, the thermal decomposition, and crystallization were performed.

In this case, as the sol-gel liquid to be applied to the part where the first thin-film element 102 was to be formed, a sol-gel liquid was used which had been prepared so as to have the composition of PZT(53/47):Nb (i.e., Pb(Zr_{0.53},Ti_{0.47})O₃:Nb₂O₅ 2 mol % is added) after crystallization. As the starting materials of the sol-gel liquid, lead acetate trihydrate, isopropoxide titanium, isopropoxide zirconium, and pentaethoxide niobium were used. Crystal water of lead acetate was dissolved in methoxyethanol and dehydrated.

The use amount of the starting materials was adjusted so that the lead amount is 10 mol % excess than that of stoichiometric composition. By doing this, the degradation of crystallinity due to lead loss during heating can be prevented.

Isopropoxide titanium, isopropoxide zirconium, and pentaethoxide niobium were dissolved in methoxyethanol and, after alcohol exchange reaction and esterification reaction were performed, were mixed with the methoxyethanol solution where the lead acetate had been resolved, to prepare the sol-gel liquid. The sol-gel liquid was prepared so that the concentration of the sol-gel liquid was 0.5 mol/litter.

Further, as the sol-gel liquid to be applied to the part where the second thin-film element 103 was to be formed, a sol-gel liquid was used which had been prepared so as to have the composition of PZT(53/27):Mn (i.e., Pb(Zr_{0.53},Ti_{0.47})O₃:MnO 2 mol % is added) after crystallization. As the starting materials of the sol-gel liquid, lead acetate trihydrate, isopropoxide titanium, isopropoxide zirconium, and diisopropoxy manganese were used. Crystal water of lead acetate was dissolved in methoxyethanol and dehydrated.

The use amount of the starting materials was adjusted so that the lead amount is 10 mol % excess than that of stoichiometric composition. By doing this, the degradation of crystalline due to lead loss during heating can be prevented.

Isopropoxide titanium, isopropoxide zirconium, and diisopropoxy manganese were dissolved in methoxyethanol and, after alcohol exchange reaction and esterification reaction were performed, were mixed with the methoxyethanol solution where the lead acetate had been resolved, to prepare the sol-gel liquid. The sol-gel liquid was prepared so that the concentration of the sol-gel liquid was 0.1 mol/litter.

The substrates, where the above sol-gel liquid is applied to the parts (areas) where the first thin-film element 102 and the second thin-film element 103 were to be formed, was heated at the temperature of 120° C. to evaporate the solution. Then, the organic substance thereof is thermally decomposed at the temperature of approximately 500° C.

Then, isopropyl alcohol washing was performed to form the SAM film again as shown in FIG. 5. In this case, since the SAM film was selectively grown by itself, the patterning for the SAM film is not necessary. Further, similar to the first application of the sol-gel liquids, the sol-gel liquids were further applied to the parts where the first thin-film element 102 and the second thin-film element 103 were to be formed by using the liquid discharge head equipped with the multi-nozzles.

Then, solution evaporation and thermal decomposition were performed. The process of the application and the thermal decomposition was repeated three cycles and then, the crystallization was performed. The crystallization was performed at the temperature of 700° C. which is the temperature in the range overlap between the optimal temperature range of the first thin-film element and the optimal temperature range of the second thin-film element as described above with reference to FIG. 6.

The first thin-film element 102 and the second thin-film element 103 were formed by repeating a process from the application of the sol-gel liquids to the thermal decomposition three cycles and then crystallization is done once, so that the thin-film having a thickness of 240 nm was formed. The process was repeated eight cycles, so that the thin-film sections having the thickness of approximately 2000 nm were formed. Further, no crack was observed in the thin-film sections in either the first thin-film element 102 or the second thin-film element 103.

As the upper electrodes, platinum films were formed on the thin-film sections of the first thin-film element 102 and the second thin-film element 103 to obtain the first thin-film element 102 and the second thin-film element 103.

The relative permittivity, the piezoelectric constant, and the power generation index of the formed first thin-film element 102 and the second thin-film element 103 were evaluated.

The piezoelectric constant (d form) was calculated by preparing the liquid chamber 211 of FIG. 2, measuring the deformed amount due to applied voltage using a laser Doppler vibrometer, and adjusting with simulation. The piezoelectric constant (d form) indicates the physical property derived from the actuator function.

The piezoelectric constant (e form) is a value calculated by dividing the piezoelectric constant (d form) by the elastic compliance, and contributes to the power generation and the sensing function.

The power generation index was calculated based on “e₃₁²/ε”. This index is called a “figure of merit (FOM)”. The greater the index is, the greater the sensing function is.

As the results of the evaluation of the first thin-film element 102, the relative permittivity was 1500, the piezoelectric constant (d form) d₃₁ was 145 pm/V, the piezoelectric constant (e form) e₃₁ was 14 C/m², and the power generation index was 0.13. Due to the piezoelectric constant (d form) d₃₁ of 145 pm/V, it is observed that the first thin-film element 102 has a sufficient displacement range as an actuator. Namely, it is observed that the first thin-film element 102 has high performance as an actuator.

Further, as the results of the evaluation of the second thin-film element 103, the relative permittivity was 1100, the piezoelectric constant (d form) d₃₁ was 108 pm/V, the piezoelectric constant (e form) e₃₁ was 13.3 C/m², and the FOM value was 0.16. Therefore, the FOM value of the second thin-film element 103 was increased by approximately 20% in comparison with the FOM value of the first thin-film element 102. Namely, the fact was observed that two different compositions can simultaneously be formed by using the ink jet print according to the present invention.

As described, according to the example of the present invention, it was observed that the electronic device was formed including two thin-film elements having different functions on the substrate. Especially, each of the thin-film elements includes the thin-film section which has the material compositions optimal to the application (function). Therefore, it becomes possible to acquire an electronic device having higher performances.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An electronic device comprising:
a substrate; and
a plurality of thin-film elements formed on the substrate,
wherein the thin-film element includes a thin-film section having a function selected from a group including piezoelectric effect, inverse piezoelectric effect, charge storage, semiconductivity, and conductivity, and
wherein the plurality of thin-film elements includes the thin-film sections having two or more different functions.

2. The electronic device according to claim 1,
wherein the thin-film element includes a thin-film section having a function selected from a group including the piezoelectric effect, the inverse piezoelectric effect, and the charge storage.

3. The electronic device according to claim 1,
wherein the plurality of thin-film elements includes thin-film sections having different material compositions.

4. The electronic device according to claim 1,
wherein the thin-film section includes a metal oxide film.

5. The electronic device according to claim 1,
wherein the thin-film elements are formed by an ink jet method.

6. The electronic device according to claim 5,
wherein the thin-film elements are formed by using a liquid discharge head equipped with multi-nozzles.

7. The electronic device according to claim 1,
wherein the plurality of thin-film elements includes a sensor and an actuator.

8. The electronic device according to claim 1,
wherein the plurality of thin-film elements includes a sensor and a power generation element.

9. The electronic device according to claim 1,
wherein the plurality of thin-film elements includes a power generation element and a charging element.

10. A method of manufacturing an electronic device, the method comprising:
a step of forming a plurality of thin-film elements on a substrate by using a liquid discharge head equipped with multi-nozzles,
wherein the thin-film element includes a thin-film section having a function selected from a group including piezoelectric effect, inverse piezoelectric effect, charge storage, semiconductivity, and conductivity, and
wherein the plurality of thin-film elements includes the thin-film sections having two or more different functions.
